(19) United States
(12) Patent Application Publication
(10) Pub. No.: US 2022/0286765 A1
(43) Pub. Date: Sep. 8, 2022

(54) SPEAKER DEVICE

(71) Applicant: Wistron Corporation, New Taipei City (TW)

(72) Inventors: Chiu-Yen Lin, New Taipei City (TW); Hua-Min Tseng, New Taipei City (TW); Shao-Ze Ma, New Taipei City (TW)

(21) Appl. No.: 17/315,369

(22) Filed: May 10, 2021

(30) Foreign Application Priority Data
Mar. 3, 2021 (TW) 110107543

(51) Int. Cl. H04R 1/02; H01L 27/32; G02F 1/1368; G02F 1/1335; H04R 9/06; H04R 9/02; H04R 7/04

(52) U.S. Cl. CPC H04R 1/028; H01L 27/322; H01L 27/3225; H01L 27/3244; G02F 1/1368; G02F 1/133514; H04R 9/06; H04R 9/025; H04R 7/04; H04R 2499/15

(57) ABSTRACT

A speaker device for a display device is disclosed. The speaker device includes: a magnet layer, disposed inside a housing of the display device; and a metal coil layer, disposed on a color filter glass of the display device, and configured to provide a motive force to the color filter glass to generate an amplitude according to a magnetic field reaction generated when a current flows through the metal coil layer.

### BACKGROUND OF THE INVENTION

### 1. Field of the Invention

The present invention relates to a speaker device, and more particularly, to a speaker device integrated with a display device.

### 2. Description of the Prior Art

A conventional display device with a speaker usually integrates the entire speaker within an electronic product such as a mobile phone, tablet, television or similar display device. Integration requires a specific reserved space, which must be arranged by the individual manufacturers. Particular care must be paid to the elements within the speaker such as coils or magnets, as any malfunction of these elements will lead to abnormal audio of the speaker device. This increases the complexity of the integration of the speaker device and the display device, as the conventional display device must have a minimum thinness to ensure correct functioning of internal elements. Therefore, improvements to the conventional techniques are necessary.

### SUMMARY OF THE INVENTION

In light of this, the present invention provides a speaker device, which is integrated with a display device using existing elements of the display device.

An embodiment of the present invention discloses a speaker device for a display device, comprising: a magnet layer disposed inside a housing of the display device; and a metal coil layer disposed on a color filter glass of the display device, and configured to provide a motive force to the color filter glass to generate an amplitude according to a magnetic field reaction generated when a current flows through the metal coil layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 and FIG. 2 are schematic diagrams of a speaker device according to an embodiment of the present invention.

FIG. 3 is a schematic diagram of a color filter glass disposed on a metal coil layer according to an embodiment of the present invention.

FIG. 4 is a schematic diagram of the metal coil layer according to an embodiment of the present invention.

FIG. 5 is a schematic diagram of a speaker device according to an embodiment of the present invention.

### DETAILED DESCRIPTION

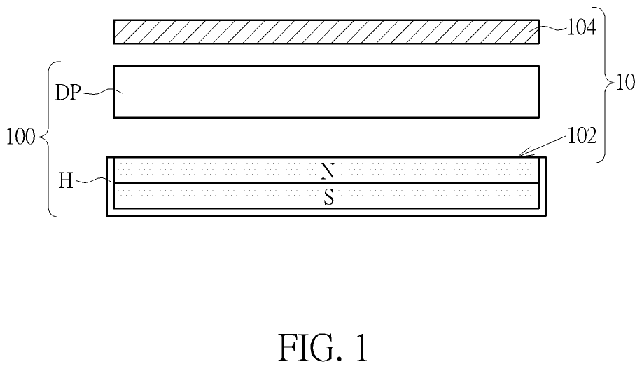

Refer to FIG. 1, which is a schematic diagram of a speaker device 10 according to an embodiment of the present invention. The speaker device 10 is disposed in a display device 100. The speaker device 10 includes a magnet layer 102 and a metal coil layer 104. The display device 100 includes a housing H and a display DP, wherein the display device 100 may be a thin film transistor liquid crystal display (TFT-LCD) or an active-matrix organic light-emitting diode (AMOLED). Since the speaker device 10 according to an embodiment of the present invention is implemented in the display device 100, the speaker device 10 may be integrated with the display device 100 to create audio using existing elements of the display device 100.

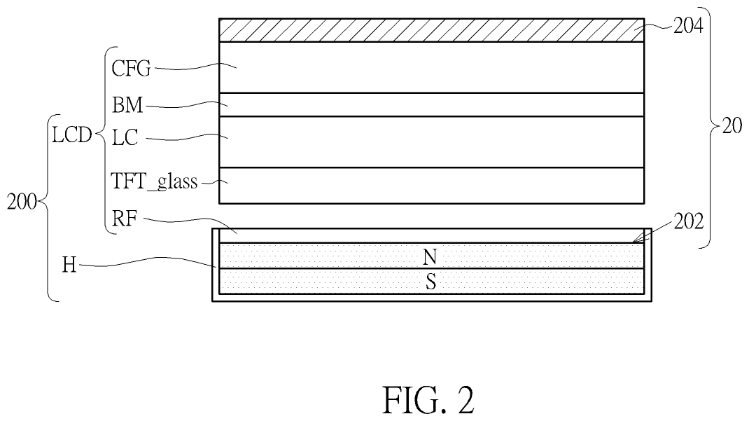

In detail, refer to FIG. 2, which is a schematic diagram of a speaker device 20 according to an embodiment of the present invention. The speaker device 20 is disposed in a display device 200; the speaker device 20 includes a magnet layer 202 and a metal coil layer 204. The display device 200 includes a housing H and a display LCD, wherein the display LCD includes a color filter glass CFG, black matrices BM, a liquid crystal layer LC, a TFT glass layer TFT_glass and a reflective film RF. As shown in FIG. 2, the magnet layer 202 of the speaker device 20 is disposed in the housing H of the display device 200 and the magnet layer 202 may be formed by a thinning magnet material, such that the magnet layer 202 may be disposed between the reflective film RF of a backlight module of the display device 200 and the housing H, wherein the housing H may be a steel housing. The metal coil layer 204 is implemented on the color filter glass CFG of the display device 200. The metal coil layer 204 may be a coating layer formed on the color filter glass CFG in a metal coating way and a photo etching way. Therefore, the metal coil layer 204 may provide a motive force to the color filter glass to generate an amplitude to the color filter glass CFG and the metal coil layer 204 according to a magnetic field reaction generated when a current flows through the metal coil layer 204. The color filter glass CFG and the metal coil layer 204 of the speaker device 20 may form a diaphragm layer of the speaker device 20, such that the magnet reaction is generated on the metal coil layer 204 when the current flows through the metal coil layer 204. In addition, contractions and expansions of the diaphragm layer of the speaker device 20 are generated according to variations of polarities of alternating current (AC) to generate sound waves and air pulses to create audio.

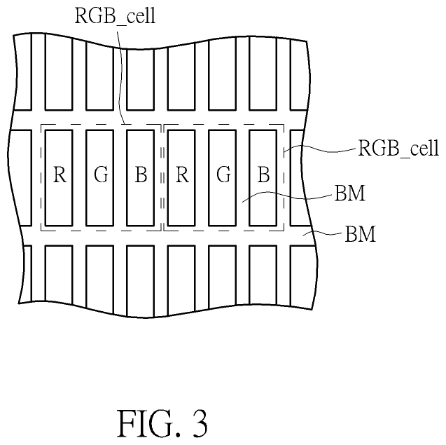

In order to prevent influencing a photoresistance penetration of the color filter glass CFG from the metal coil layer 204 of the speaker device 20, coil traces of the metal coil layer 204 are implemented along the black matrices BM of the display LCD. Refer to FIG. 3, which is a schematic diagram of the color filter glass CFG disposed on the metal coil layer 204 according to an embodiment of the present invention. As shown in FIG. 3, the color filter glass CFG of the display LCD includes a plurality of photoresist pixels RGB_pixel, where each photoresist pixel RGB_pixel includes a red photoresist subcell R_pixel, a green photoresist subcell G_pixel, and a blue photoresist subcell B_pixel. The black matrices BM are utilized for preventing color mixture of the red photoresist subcells R_pixel, the green photoresist subcells G_pixel and the blue photoresist subcells B_pixel, which may effectively segment the red photoresist subcells R_pixel, the green photoresist subcells G_pixel, and the blue photoresist subcells B_pixel. Therefore, the metal coil layer 204 according to an embodiment of the present invention may be implemented along the black matrices BM to avoid influencing the photoresistance penetration.

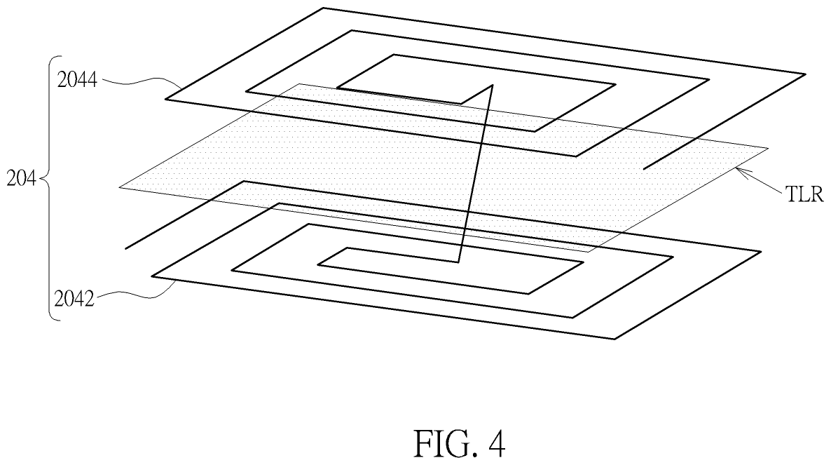

Refer to FIG. 4, which is a schematic diagram of the metal coil layer 204 according to another embodiment of the present invention. The metal coil layer 204 according to an embodiment of the present invention may be implemented by a single coil layer or multiple coil layers. For example, as shown in FIG. 4, the metal coil layer 204 is composed of a single coil layer 2042, or the metal coil layer 204 is composed of a coil layer 2042 and a coil layer 2044, and a transparent photoresist TLR exists between each of the coil layers. Notably, the number of coil layers of the metal coil layer 204 is not limited to that shown in the embodiment in FIG. 4 and may be adjusted according to different requirements.

In addition, according to an embodiment of the present invention, a highly-reflective and non-magnetic material coating may be formed on a north pole (N) of the magnet layer 202 as the reflective film RF of the backlight module of the display device 200 for thinning the coating, wherein the highly-reflective and non-magnetic material coating may be a coating material, which is not Fe, Co or Ni.

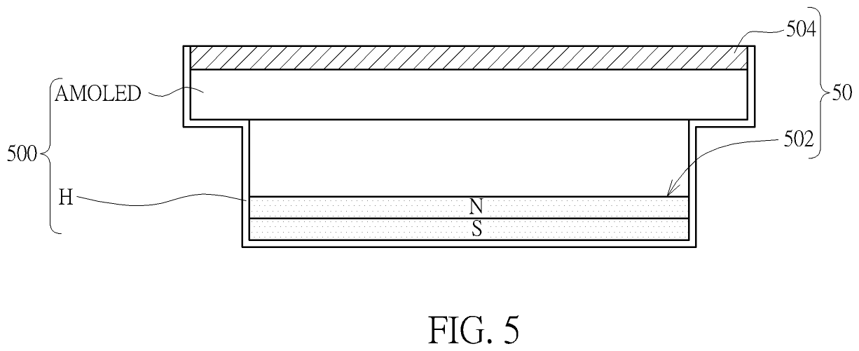

Refer to FIG. 5, which is a schematic diagram of a speaker device 50 according to another embodiment of the present invention. The speaker device 50 is disposed in a display device 500. The speaker device 50 includes a magnet layer 502 and a metal coil layer 504, and the display device 500 includes a housing H and a display AMOLED. As shown in FIG. 5, the magnet layer 502 of the speaker device 50 is implemented in the housing H of the display device 500, and the magnet layer 502 may be formed by a thinning magnet material. Similar to the embodiment of FIG. 2, the metal coil layer 504 may be a coating layer formed on the display AMOLED in a metal coating way and a photo etching way. Therefore, the metal coil layer 504 is configured to provide a motive force to the display AMOLED, and the metal coil layer 504 generates an amplitude according to a magnetic field reaction generated when a current flows through the metal coil layer 504. When the current flows through the metal coil layer 504, the magnet reaction is generated, and contractions and expansions of the metal coil layer 504 of the speaker device 50 are generated according to variations of the polarities of AC to generate sound waves and air pulses to create audio.

Notably, those skilled in the art may make proper modifications to the speaker device of the present invention according to different system requirements. For example, methods of forming the metal coil layer and the materials of the magnet layer may be adjusted according to different requirements, which are not limited thereto. These modifications all belong to the scope of the present invention.

In summary, the present invention provides a speaker device, which is integrated in a display device utilizing existing elements of the display device, such that manufacturing costs are decreased and thinning of the integrated speaker device is achieved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A speaker device, for a display device, comprising:
a magnet layer, disposed inside a housing of the display device; and
a metal coil layer, disposed on a color filter glass of the display device, and configured to provide a motive force to the color filter glass to generate an amplitude according to a magnetic field reaction generated when a current flows through the metal coil layer.

2. The speaker device of claim 1, wherein the metal coil layer is a coating layer formed on the color filter glass in a metal coating way and a photo etching way.

3. The speaker device of claim 1, wherein the display device includes a display disposed between the magnet layer and the metal coil layer.

4. The speaker device of claim 3, wherein the display is a thin film transistor liquid crystal display (TFT-LCD), and coils of the metal coil layer are disposed above black matrices of the TFT-LCD.

5. The speaker device of claim 3, wherein when the display is an Active-matrix organic light-emitting diode (AMOLED), coils of the metal coil layer are disposed on the AMOLED.

6. The speaker device of claim 1, wherein the magnet layer is formed by a thinning magnet material.

7. The speaker device of claim 6, wherein a north pole of the thinning magnet material includes a highly-reflective and non-magnetic material coating as a reflective film of a backlight module of the display device.

8. The speaker device of claim 1, wherein the color filter glass and the metal coil layer form a diaphragm layer of the speaker device.

9. The speaker device of claim 1, wherein the metal coil layer is composed of at least a single coil layer, and when the metal coil layer is composed of a plurality of coil layers, a transparent photoresist exists between each of the plurality of coil layers.
